(19) United States
(12) Patent Application Publication
(10) Pub. No.: US 2007/0279971 A1
(43) Pub. Date: Dec. 6, 2007

(54) MODIFIED PSEUDO-SPIN VALVE (PSV) FOR MEMORY APPLICATIONS

(75) Inventors: Timothy J. Vogt, Elk River, MN (US); Romney R. Katti, Maple Grove, MN (US); Dan J. Schipper, Andover, MN (US); Theodore Zhu, Mission Viejo, CA (US); Anthony Arrott, Washington, DC (US); Joel A. Drewes, Boise, ID (US); Harry Liu, Plymouth, MN (US); William Larson, Chippewa Township, WI (US)

Correspondence Address: KNOBBE MARTENS OLSON & BEAR LLP, 2040 MAIN STREET, FOURTEENTH FLOOR, IRVINE, CA, 92614, US

(73) Assignee: MICRON TECHNOLOGY, INC., Boise, ID (US)

(21) Appl. No.: 11/535,893

(22) Filed: Sep. 27, 2006

Related U.S. Application Data
(63) Continuation of application No. 11/144,729, filed on Jun. 3, 2005.
(60) Provisional application No. 60/577,092, filed on Jun. 4, 2004.

(51) Int. Cl. G11C 11/00

(52) U.S. Cl. 365/158

(57) ABSTRACT

A pseudo-spin valve for memory applications, such as magnetoresistive random access memory (MRAM), and methods for fabricating the same, are disclosed. Advantageously, memory devices with the advantageous pseudo-spin valve configuration can be fabricated without cobalt-iron and without anti-ferromagnetic layers, thereby promoting switching repeatability.

### RELATED APPLICATION

This application is a continuation application of U.S. application Ser. No. 11/144,729, filed Jun. 3, 2005, which claims the benefit under 35 U.S.C. § 119(e) of U.S. Provisional Application No. 60/577,092, filed Jun. 4, 2004, the disclosures of which are hereby incorporated by reference.

### GOVERNMENT RIGHTS

This invention was made with Government support under Contract Number MDA972-98-C-0021 awarded by DARPA. The Government has certain rights in this invention.

### BACKGROUND OF THE INVENTION

1. Field of the Invention

The invention generally relates to non-volatile memory technology. In particular, the invention relates to a pseudo-spin valve for memory applications.

### DESCRIPTION OF THE RELATED ART

Computers and other digital systems use memory to store programs and data. A common form of memory is random access memory (RAM), such as dynamic random access memory (DRAM) devices and static random access memory (SRAM) devices. DRAM devices and SRAM devices are volatile memories. A volatile memory loses its data when power is removed. For example, when a conventional personal computer is powered off, the volatile memory is reloaded through a boot up process when the power is restored. In addition, certain volatile memories such as DRAM devices require periodic refresh cycles to retain their data even when power is continuously supplied.

In contrast to the potential loss of data encountered in volatile memory devices, nonvolatile memory devices retain data for long periods of time when power is removed. Examples of nonvolatile memory devices include read only memory (ROM), programmable read only memory (PROM), erasable PROM (EPROM), electrically erasable PROM (EEPROM), flash memory, and the like. Disadvantageously, conventional nonvolatile memories are relatively large, slow, and expensive. Further, conventional nonvolatile memories are relatively limited in write cycle capability and typically can only be programmed to store data about 10,000 times in a particular memory location. This prevents a conventional non-volatile memory device, such as a flash memory device, from being used as general purpose memory.

An alternative memory device is known as magnetoresistive random access memory (MRAM). An MRAM device uses magnetic orientations to retain data in its memory cells. Advantageously, MRAM devices are relatively fast, are nonvolatile, consume relatively little power, and do not suffer from a write cycle limitation. There are at least three different types of MRAM devices, including giant magneto-resistance (GMR) MRAM devices, magnetic tunnel junction (MTJ) or tunneling magneto-resistance (TMR) MRAM devices, and pseudo-spin valve (PSV) MRAM devices. GMR MRAM devices separate at least two ferromagnetic layers with a conductive layer. In a MTJ MRAM device, at least two ferromagnetic layers are separated by a thin insulating tunnel barrier, such as a layer of aluminum oxide. A PSV MRAM device uses an asymmetric sandwich of the ferromagnetic layers and metallic layer as a memory cell, and the ferromagnetic layers do not switch at the same time.

However, conventional MRAM devices can suffer from many drawbacks. For example, ferromagnetic layers made wholly or partially with cobalt-iron (CoFe) can exhibit relatively low switching repeatability. In addition, conventional MRAM devices can disadvantageously require additional processing steps, such as processing steps to fabricate anti-ferromagnetic layers.

### SUMMARY OF THE INVENTION

The invention relates to a new pseudo-spin valve for memory applications, such as magnetoresistive random access memory (MRAM). Advantageously, new memory devices with the advantageous pseudo-spin valve configuration can be fabricated without cobalt-iron and without anti-ferromagnetic layers.

One embodiment corresponds to a pseudo-spin valve (PSV) in a magnetic random access memory (MRAM) including: a hard layer including magnetic material, where the magnetic material of the hard layer consists of nickel-iron material; a soft layer including magnetic material, where the magnetic material of the soft layer also consists of nickel-iron material, where the soft layer is thinner than the hard layer such that the soft layer switches at a lower field than the hard layer; and a conductive spacer layer disposed between the hard layer and the soft layer, where the conductive spacer layer is non-ferromagnetic. For example, the nickel-iron material can correspond to permalloy, which is about 80% nickel and 20% iron. In one embodiment, the nickel-iron material corresponds to a composition that is about 50-90% nickel. In another embodiment, the nickel-iron material corresponds to a composition that is about 70-85% nickel. It will be understood that the nickel-iron material can include impurities ordinarily associated with nickel-iron.

One embodiment corresponds to a pseudo-spin valve (PSV) in a magnetic random access memory (MRAM) comprising: a hard layer including magnetic material, where the magnetic material of the hard layer consists of nickel-iron material; a non-ferromagnetic conductive spacer layer adjacent to the hard layer; a soft layer including magnetic material adjacent to the spacer layer such that the spacer layer is disposed between the hard layer and the soft layer, where the magnetic material of the soft layer consists of nickel-iron material, where the soft layer is thinner than the hard layer so that the soft layer switches at a lower field than the hard layer; where the PSV does not include an anti-ferromagnetic layer; and where the PSV does not include a layer that consists of cobalt-iron materials. Advantageously, the PSV for the MRAM can be fabricated without the disadvantages of an anti-ferromagnetic layer and a layer with cobalt-iron.

One embodiment corresponds to a system, where the system includes: a control unit for performing a series of instructions; and a magnetic random access memory (MRAM) in a pseudo-spin valve (PSV) configuration responsive to the control unit, the memory comprising: a hard layer including magnetic material, where the magnetic material of the hard layer consists of nickel-iron material; a soft layer including magnetic material, where the magnetic material of the soft layer consists of nickel-iron material, where the soft layer is thinner than the hard layer such that the soft layer switches at a lower field than the hard layer; and a conductive spacer layer disposed between the hard layer and the soft layer, where the conductive spacer layer is non-ferromagnetic.

One embodiment corresponds to a computer system, where the computer system includes: a processor; at least one storage device communicably coupled to the processor; at least one input/output device communicably coupled to the processor; a memory device communicably coupled to the processor, the memory device having at least one pseudo-spin valve (PSV) memory cell comprising: a hard layer, where the hard layer consists of nickel-iron material; a non-ferromagnetic conductive spacer layer adjacent to the hard layer; a soft layer adjacent to the spacer layer such that the spacer layer is disposed between the hard layer and the soft layer, where the soft layer consists of nickel-iron material, where the soft layer is thinner than the hard layer so that the soft layer switches at a lower field than the hard layer; where the PSV memory cell does not include an anti-ferromagnetic layer; and where the PSV memory cell does not include a layer that includes cobalt-iron materials.

One embodiment corresponds to a method of fabricating a pseudo-spin valve (PSV) in a magnetic random access memory (MRAM), the method comprising: providing a substrate assembly; forming a first magnetic layer, where a magnetic material of the first magnetic layer consists of nickel-iron; forming a spacer layer on the first magnetic layer, where the spacer layer is formed from a material that is conductive and is not magnetic; and forming a second magnetic layer on the spacer layer such that the spacer layer is between the first magnetic layer and the second magnetic layer, where a magnetic material of the second magnetic layer consists of nickel-iron, wherein one of the first magnetic layer and the second magnetic layer is formed to a thickness between about 20% to about 80% of the thickness of the other; not forming an anti-ferromagnetic layer for the PSV; and not forming a layer with cobalt-iron in the PSV.

### BRIEF DESCRIPTION OF THE DRAWINGS

These and other features of the invention will now be described with reference to the drawings summarized below. These drawings and the associated description are provided to illustrate preferred embodiments of the invention and are not intended to limit the scope of the invention.

FIG. 1 is a perspective view illustrating a giant magneto-resistance (GMR) cell in a spin valve mode.

FIG. 2 is a schematic top-down view illustrating an array of GMR cells.

FIG. 3 illustrates a GMR cell in a pseudo-spin valve (PSV) mode.

FIG. 4 is a cross-sectional view of a magnetoresistive stack for an pseudo-spin valve (PSV) according to an embodiment of the invention.

FIG. 5 is an R—H plot (ΔR/Rₘᵢₙ) of a PSV illustrating thresholds for writing data to a PSV cell or bit when the PSV cell is not selected.

FIG. 6 is an R—H plot (ΔR/Rₘᵢₙ) of a PSV illustrating thresholds for writing data to a PSV cell or bit when the PSV cell is selected.

FIG. 7 is an R—H plot (ΔR/Rₘᵢₙ) of a PSV illustrating thresholds for writing data to an array of PSV cells when the array of PSV cells is not selected.

FIG. 8 is an R—H plot (ΔR/Rₘᵢₙ) of a PSV illustrating thresholds for writing data to an array of PSV cells when the array of PSV cells is selected.

FIG. 9 illustrates repeatability in a PSV bit or cell.

FIG. 10 illustrates bit-to-bit or cell-to-cell repeatability.

### DETAILED DESCRIPTION OF THE PREFERRED EMBODIMENTS

Although this invention will be described in terms of certain preferred embodiments, other embodiments that are apparent to those of ordinary skill in the art, including embodiments that do not provide all of the benefits and features set forth herein, are also within the scope of this invention. Accordingly, the scope of the invention is defined only by reference to the appended claims.

A magnetoresistive random access memory (MRAM) stores data in magnetic states of its memory cells. The electrical resistance of the cell depends on the stored magnetic state of the cell. The stored state of the cell is detected by sensing a difference in resistance. In one embodiment, the MRAM is used in a system with a control unit, such as a central processing unit (CPU) or processor. The control unit executes a series of instructions, and the MRAM is coupled to and is responsive to the control unit. One embodiment is a computer system. The computer system can include a processor, at least one storage device, such as a hard disk, and optical disk, and the like, communicably coupled to the processor; at least one input/output device, such as a keyboard, mouse device, monitor, and the like, communicably coupled to the processor. and a memory device having MRAM cells.

New pseudo-spin valves for memory applications, such as magnetoresistive random access memory (MRAM), and methods for fabricating the same are disclosed. Advantageously, new memory devices with the advantageous pseudo-spin valve configuration can be fabricated without cobalt-iron and without anti-ferromagnetic layers. A pseudo-spin valve (PSV) with only nickel-iron magnetic layers and without cobalt-iron can advantageously operate with improved switching characteristics, such as improved repeatability. Improving switching characteristics can lead to improved production yields. Compared to a PSV with an anti-ferromagnetic layer, a PSV without anti-ferromagnetic layers advantageously reduces the risk of pinning dispersive or dispersed moments in the soft and/or thin reference layer and advantageously permits a higher field pulse to be used to reset a state of the PSV. In addition, the read and the write characteristics for PSVs with and without anti-ferromagnetic layers differ. For example, compared to a PSV with an anti-ferromagnetic layer, a PSV without an anti-ferromagnetic layer writes data with a relatively higher magnetic field and reads data with a relatively lower magnetic field. The reading of data from a bit using a relatively lower field advantageously decreases the chances of undesirably overwriting an adjacent bit while performing a data read.

One drawback to not using cobalt-iron in a PSV stack is that the use of nickel-iron alone over cobalt-iron will typically reduce the change in resistance (ΔR/R) for the PSV stack from about 4% to about 2%. This disadvantage can be overcome by adjusting the sensitivity of a sense amplifier to compensate, by lengthening the bit or cell to increase the total resistance, and the like.

Another drawback to not using cobalt-iron is a reduction in the thermal stability during processing of a nickel-iron PSV stack over the processing of a PSV stack fabricated from cobalt-iron. To compensate, fabrication of the nickel-iron PSV memory devices can be tailored to lower temperatures, by, for example, using a relatively low-temperature dielectric, such as polyimide, parylene, alumina, and the like, in place of relatively high-temperature dielectrics. For example, these insulating layers of dielectric material can be formed between layers of PSV arrays, between cells of an array, between conductors, and the like. In one embodiment, a relatively high-temperature dielectric, such as silicon nitride, is sputtered at a relatively low temperature. In one embodiment, a maximum temperature associated with forming of insulating films is about 220 degrees centigrade.

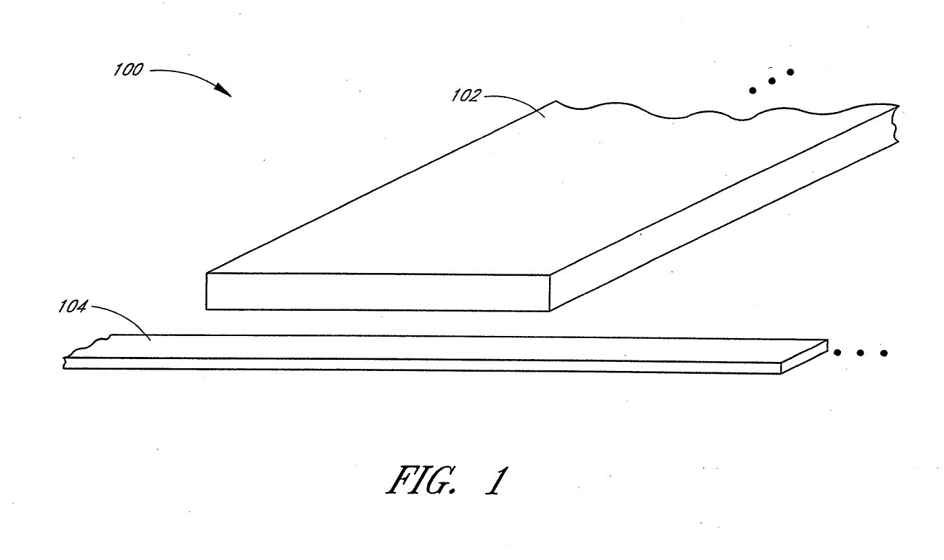

FIG. 1 is a perspective view illustrating a GMR cell 100 in a spin valve mode. The GMR cell 100 includes a word line 102 and a bit line 104. In a GMR cell, the bit line 104 is also known as a sense line. The bit line 104 contains magnetic layers. Data is stored in a cell body portion of the bit line 104 by simultaneously applying current through the word line 102 and the bit line 104. The direction of the current in the word line 102 (and the consequent magnetic field applied) can determine the polarization of the magnetic orientation that stores the logical state of the data while the current in the bit line 104 assists the writing process. For example, the applied field component from the word line current can be clockwise around the word line 102 for a first current direction, and counterclockwise around the word line 102 for a second current direction. The additional magnetic field applied from the bit line 104 can be used to select a cell in an array of cells.

To read data from the GMR cell 100, current can again be applied to the bit line 104 corresponding to the GMR cell 100. In some embodiments, such as pseudo-spin valve GMR cells, currents can be applied to both the word line 102 and to the bit line 104 corresponding to the GMR cell 100 to read a stored state of the cell. In one configuration of an array of cells, where multiple cells can share a word line or a bit line, a combination of word line current and bit line current can be used to select and to read a state from a cell in the array. The resistance encountered by the current applied to the bit line 104 depends on the logical state stored in the magnetic layers. The current through a cell with a larger resistance causes a larger voltage drop than the current through a cell with a smaller resistance.

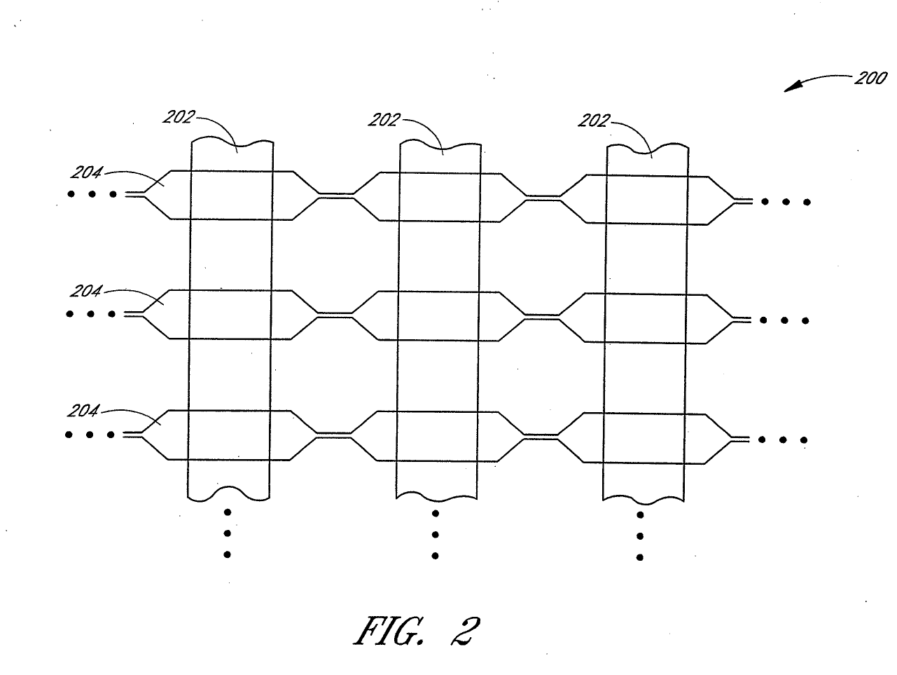

FIG. 2 is a schematic top-down view illustrating an array 200 of GMR cells. A plurality of cells are arranged into the array 200 in a memory device. The array 200 of cells includes a plurality of word lines 202 and a plurality of bit lines 204. An individual cell within the array 200 is selected by applying current through the corresponding word line and the corresponding bit line. Data is not stored or read in a cell where current flows through only the word line of the cell or through only the bit line of the cell.

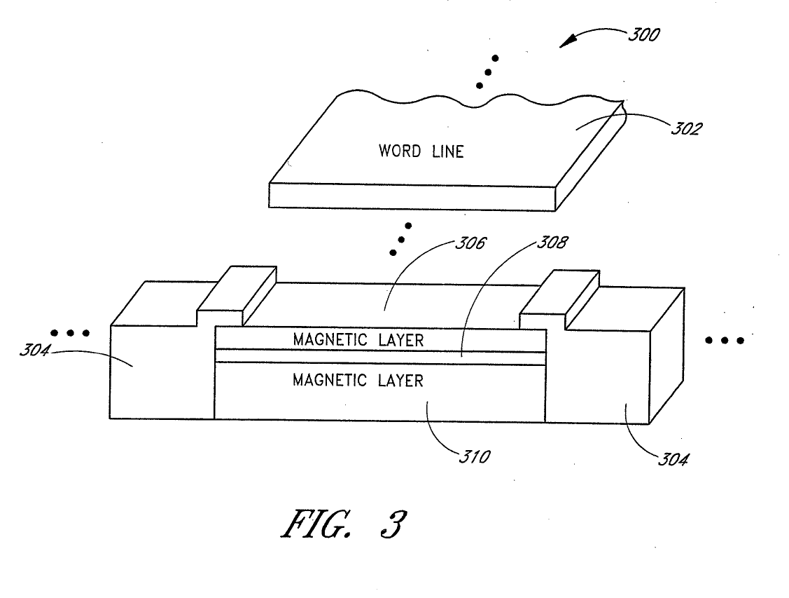

FIG. 3 illustrates a GMR cell 300 in a pseudo-spin valve (PSV) mode. The GMR cell 300 includes a word line 302 and a bit line 304. The bit line 304 of the GMR cell 300, which is also known as a sense line, further includes a GMR stack including a first magnetic layer 306, a conductive layer 308, and a second magnetic layer 310. The first magnetic layer 306 and the second magnetic layer 310 are mismatched so that the first magnetic layer 306 is magnetically “softer” than the second magnetic layer 310. As is known in the art, the mismatch in magnetic properties can be obtained by making the first magnetic layer 306 relatively thin as compared to the second magnetic layer 310, by selecting a relatively soft magnetic material for the first magnetic layer 306 and a relatively hard magnetic material for the second magnetic layer 310, or by making the first magnetic layer 306 thinner and magnetically softer than the second magnetic layer 310. Other terms used to describe a “hard layer” include “pinned layer” and “fixed layer.” However, it will be understood by one of ordinary skill in the art that the stored magnetic orientation in a hard layer can be varied in accordance with the logical state of the stored data. Other terms used to describe a “soft layer” include “variable layer” and “flipped layer.” It will be understood by one of ordinary skill in the art that the GMR stack can further include multiple layers of ferromagnetic materials and spacers.

The GMR cell 300 stores data as a magnetic orientation in the second magnetic layer 310. A relatively high magnetic field is required to switch the magnetization of the second magnetic layer 310 so that the magnetization remains fixed in operation. The magnetic state of the GMR cell 300 is switched by switching the magnetization of the first magnetic layer 306, which can be switched with a relatively low magnetic field generated by applying a current to the corresponding word line 302 and applying a current to the corresponding bit line 304. The resulting magnetization of the first magnetic layer 306 is either parallel or anti-parallel to the magnetization of the second magnetic layer 310. When the magnetization in the first magnetic layer 306 is parallel with the magnetization of the second magnetic layer 310, the electrical resistance of the GMR cell 300 is lower than when the magnetization of the first magnetic layer 306 is relatively anti-parallel to the magnetization of the second magnetic layer 310. Current in the word line 302 and/or the bit line 304 can be switched in both directions to correspondingly switch the magnetization of the first magnetic layer 306 (i.e., the soft magnetic layer) between parallel and anti-parallel states. The difference in electrical resistance of the bit line 304 is then sensed, thereby allowing the stored logical state of the GMR cell 300 to be retrieved.

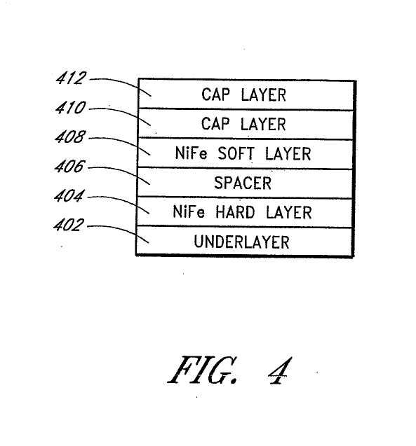

FIG. 4 is a cross-sectional view of a magnetoresistive stack 400 for an pseudo-spin valve (PSV) according to an embodiment of the invention. The illustrated magnetoresistive stack 400 includes an underlayer 402, a nickel-iron (NiFe) hard layer 404, a spacer layer 406, a nickel-iron (NiFe) soft layer 408, a first cap layer 410, and a second cap layer 412. The underlayer 402 or seeding layer preferably provides adhesion between an underlying layer in the substrate and the nickel-iron (NiFe) hard layer 404, such as by providing texture to the stack. The underlayer 402 can also include one or more barrier layers to protect against the undesired diffusion of atoms from the nickel-iron (NiFe) hard layer 404 to an underlying layer, such as a silicon substrate. A variety of materials can be used for the underlayer 402. In one embodiment, the underlayer 402 is formed from tantalum (Ta). Other materials that can be used for the underlayer 402 include titanium (Ti), ruthenium (Ru), nickel-iron chromium (NiFeCr), and tantalum nitride (TaN). The underlayer 402 can be formed to a broad range of thicknesses. In one embodiment, the underlayer 402 is within a range of about 10 Angstroms (Å) to about 100 Å thick. Various processing techniques, such as physical vapor deposition (PVD) techniques, chemical vapor deposition (CVD) techniques, and the like, can be used to form the various layers described herein.

The nickel-iron (NiFe) hard layer 404 (or thick layer) stores the data for the PSV cell. A relatively large word current, which generates a relatively large magnetic field, switches the orientation of the magnetic moment stored in the nickel-iron (NiFe) hard layer 404 to store data. Advantageously, the nickel-iron (NiFe) hard layer 404 is formed from an alloy of nickel-iron, such as permalloy. As used herein, permalloy refers to a composition that is about 80% nickel and 20% iron. It should be noted that in the literature, such as, for example, Non-Volatile Memory (MRAM) ANXXX, [online] Honeywell <URL: http://www.ssec.honeywell.com/avionics/h_gmr.pdf> pp. 1-4, a composition of cobalt, nickel, and iron can be referred to as “cobalt-permalloy,” and then later referred to as “permalloy,” when in fact the composition includes cobalt and does not correspond to a nickel-iron as described herein. Returning now to FIG. 4, in one embodiment, the nickel-iron (NiFe) hard layer 404 is within a range of about 20 Å to about 100 Å thick.

The spacer layer 406 is a nonmagnetic layer that separates the magnetic layers. The spacer layer 406 can be formed from a broad variety of non-ferromagnetic materials. A broad variety of materials can be used to form the spacer layer 406. In one embodiment, the spacer layer 406 is a conductive material, such as copper (Cu). Alloys of copper are also suitable materials, such as copper silver (CuAg), copper gold silver (CuAuAg), and the like. In one example, the thickness of the spacer layer 406 of conductive material is within a range of about 18 Å to about 45 Å.

The magnetic moment of the nickel-iron (NiFe) soft layer 408 (or thin layer) can be switched or flipped with relatively low word currents and relatively low magnetic fields. When the magnetic moment of the nickel-iron (NiFe) soft layer 408 and the magnetic moment of the nickel-iron (NiFe) hard layer 404 are parallel, the resistance of the PSV cell is relatively low. When the magnetic moment of the nickel-iron (NiFe) soft layer 408 and the magnetic moment of the nickel-iron (NiFe) hard layer 404 are anti-parallel, the resistance of the PSV cell is relatively high. The nickel-iron (NiFe) soft layer 408 is formed from an alloy of nickel-iron, such as permalloy. In one embodiment, the thickness of the nickel-iron (NiFe) soft layer 408 is about 20% to about 80% of the thickness of the nickel-iron (NiFe) hard layer 404. In one embodiment, the nickel-iron (NiFe) soft layer 408 is fabricated from the same alloy as the nickel-iron (NiFe) hard layer 404.

The first cap layer 410 (or protective cap layer) provides adhesion to the nickel-iron (NiFe) soft layer 408 and provides a barrier against the undesired diffusion of atoms from the nickel-iron (NiFe) soft layer 408 to other layers in the substrate assembly. In one embodiment, the first cap layer 410 is formed from tantalum (Ta). Other materials that can be used for the first cap layer 410 include copper (Cu), titanium nitride (TiN), and the like. The thickness of the first cap layer 410 can vary in a broad range. In one embodiment, the thickness of the first cap layer 410 is within about 50 Å to about 500 Å.

The second cap layer 412 (or diffusion barrier cap layer) is an optional layer. For some etching processes, the addition of the second cap layer 412 provides a relatively good stopping layer. In one embodiment, the second cap layer 412 is a layer of chromium silicon (CrSi). Other materials that can be used for the second cap layer 412 include copper (Cu), tantalum (Ta), titanium nitride (TiN), and the like. In one embodiment, the thickness of the second cap layer 412 is within a range of about 100 Å to about 200 Å thick, but it will be understood by one of ordinary skill in the art that the thickness can vary within a broad range.

In one embodiment, the fabrication of the memory devices further includes a relatively brief annealing procedure. The annealing can take place after forming of the bits or cells, or after forming of the memory device. An appropriate temperature range for annealing is about 200 to about 220 degrees centigrade. Annealing can be performed for a broad range of time periods. In one example, annealing is performed for a time period in a range of about 1 to about 2 hours. In another example, annealing is performed for a time period in a range of about 10 minutes to about 4 hours. Other appropriate time periods will be readily determined by one of ordinary skill in the art. Annealing advantageously improves the switching of the memory devices.

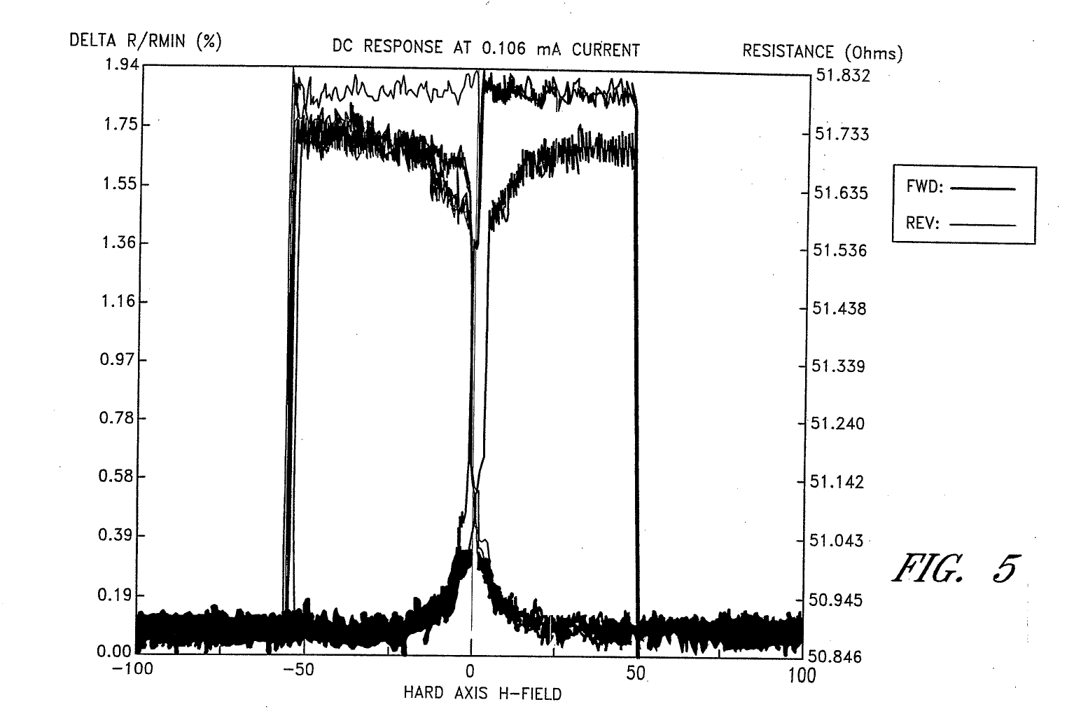

FIGS. 5-8 are R—H test plots of an example of the pseudo-spin valve (PSV) described earlier in connection with FIG. 4. In the illustrated test plots, nickel-iron material for the PSV corresponded to approximately 80% nickel and 20% iron. It will be understood by one of ordinary skill in the art that the test results will vary substantially in accordance with a selection of layer thicknesses, cell geometries, and the like. In FIGS. 5-8, a vertical axis, i.e., the y-axis, corresponds to resistance and has units of ohms as indicated to the far right of FIGS. 5-8. To the far left of FIGS. 5-8, the resistance is also indicated as a percentage change based on the minimum resistance shown for the respective figure. A horizontal axis, i.e., the x-axis, indicates magnetic field strength and has units of oersteds (Oe).

FIG. 5 is an R—H plot taken from an example of the magnetoresistive stack 400 described earlier in connection with FIG. 4. The R—H plot of FIG. 5 illustrates the resistance of the magnetoresistive stack 400 versus a first magnetic field (“H-field”) that is swept along one axis of the magnetoresistive stack 400. The applied first H-field is represented along a horizontal or x-axis of FIG. 5. No other H-field is applied to the magnetoresistive stack 400, so that the data in FIG. 5 is representative of the conditions that the magnetoresistive stack 400 would encounter in operation when the corresponding PSV cell is not selected. A first set of data lines correspond to data taken with the first H-field swept in one direction, termed a forward direction; and a second set of data lines correspond to data taken with the first H-field swept in the opposite direction, termed a reverse direction.

As illustrated in FIG. 5, the magnetoresistive stack 400 advantageously does not switch until the magnitude of the first H-field has reached about 49-56 Oe, which is relatively high. This indicates that nickel-iron PSV cells that are not selected can tolerate a relatively high H-field without losing data.

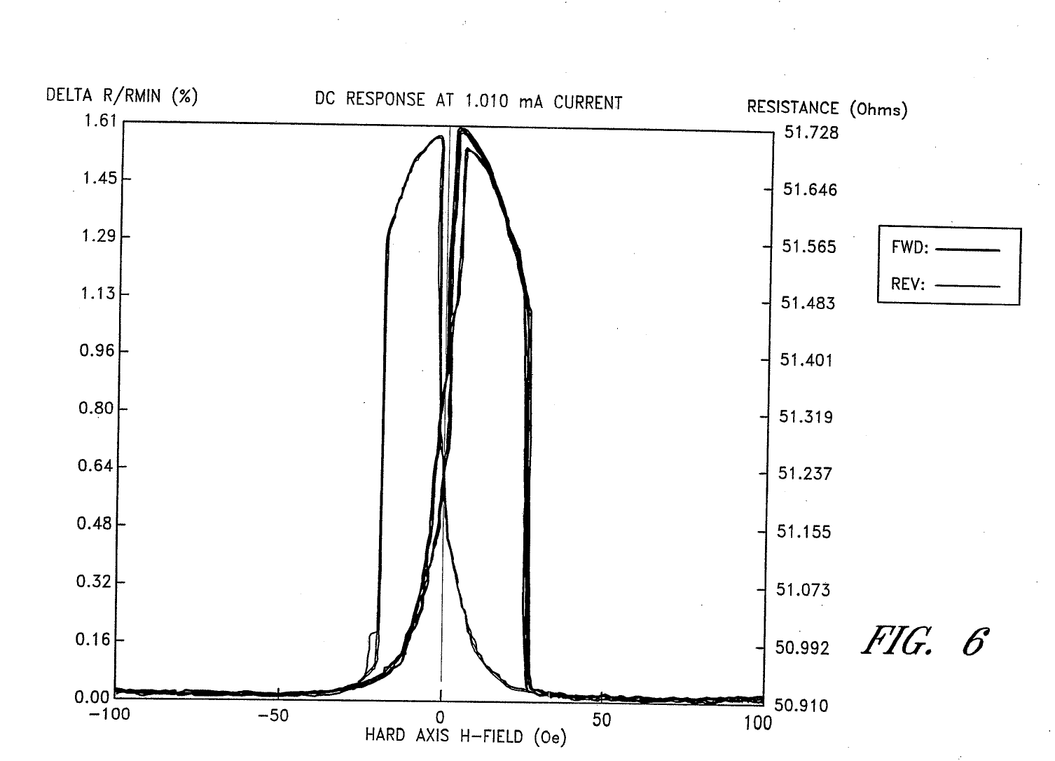

FIG. 6 is an R—H plot of the example of the magnetoresistive stack 400 described earlier in connection with FIG. 4. The R—H plot of FIG. 6 again illustrates the resistance of the magnetoresistive stack 400 versus the first H-field. However, a second H-field that is approximately orthogonal to the first H-field of about 60 Oe is also applied to the magnetoresistive stack 400 for the data shown in FIG. 6. The second H-field approximates the H-field that would be generated by a current flowing through a conductor that is used to select the PSV cell with the magnetoresistive stack 400 from an array of nickel-iron PSV cells in an MRAM. This second H-field is sometimes referred to in the art as a “digital” field.

The horizontal or x-axis represents the first H-field that is swept along one axis of the magnetoresistive stack 400. When the magnetoresistive stack 400 is subjected to the second H-field, the magnetoresistive stack 400 switches for a write when the magnitude of the first H-field is about 20-27 Oe. This is lower than the approximately 49-56 Oe described earlier in connection with FIG. 5, and indicates that a write to a selected PSV cell can occur without undesirably overwriting the contents of a PSV cell that was not selected.

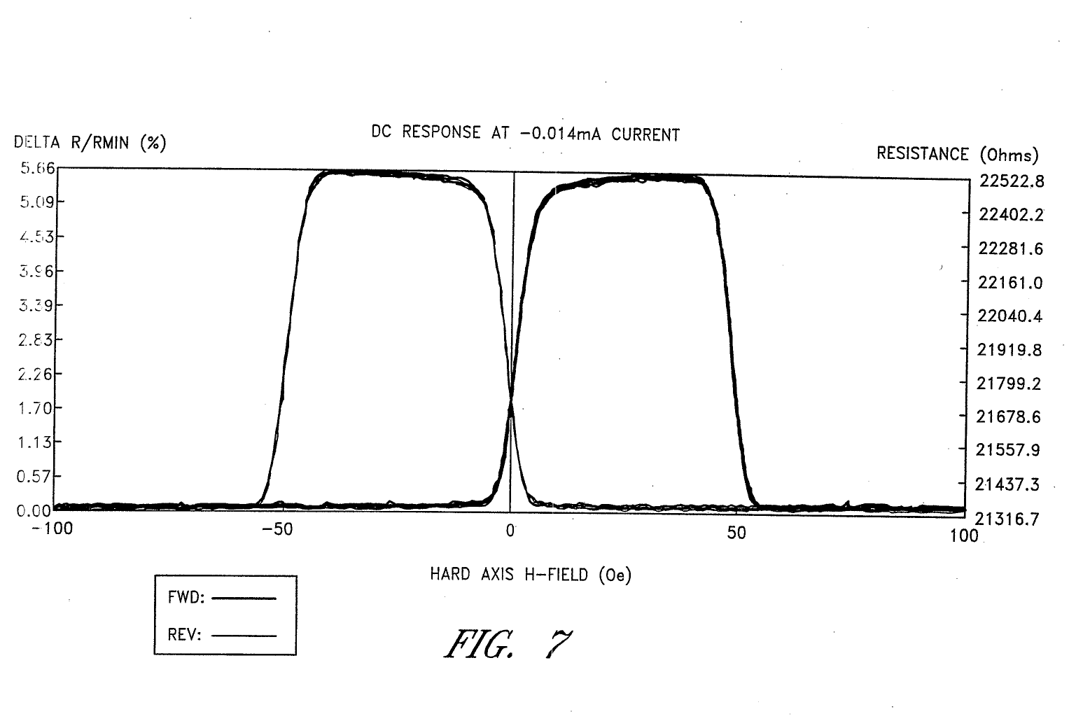

FIG. 7 is an R—H plot (ΔR/Rₘᵢₙ) of a PSV illustrating simulated thresholds for writing data to cells of an array of PSV cells when the cells of the array of PSV cells are not selected, as simulated by an absence of an externally-applied H-field of the illustrated example. Advantageously, when cells of the array are not selected by an approximately orthogonal H-field, the write thresholds are relatively high, at about 52-53 Oe in the illustrated example.

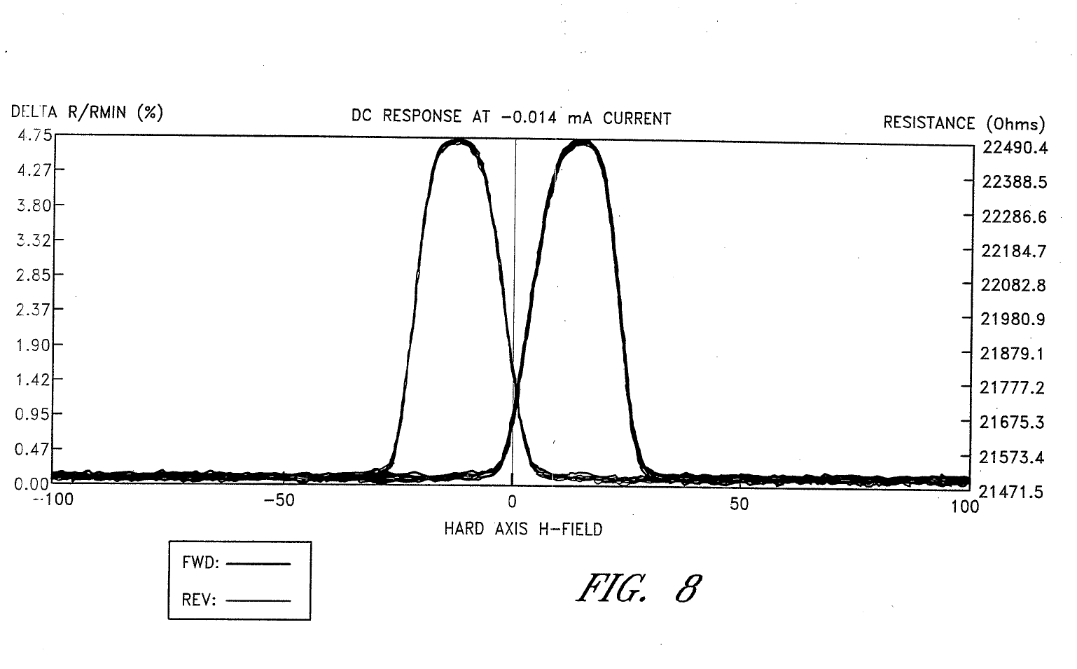

FIG. 8 is an R—H plot (ΔR/Rₘᵢₙ) of a PSV illustrating simulated thresholds for writing data to cells of an array of PSV cells when the cells of the array of PSV cells are selected, as simulated by a presence of an externally-applied H-field of the illustrated example. In the illustrated example, the selection of the array of PSV cells was simulated by exposing the PSV cells to an approximately orthogonal H-field of about 60 Oe. Advantageously, when cells of the array are selected as simulated by the approximately orthogonal H-field, the write thresholds are relatively low, at about 26 to 28 Oe in the illustrated example. It should be noted that the externally-applied H-field described above is applied to all the cells of the array for test or simulation purposes, and that within a memory device, an appropriate H-field, such as a digital field, is internally generated to select a particular cell or group of cells.

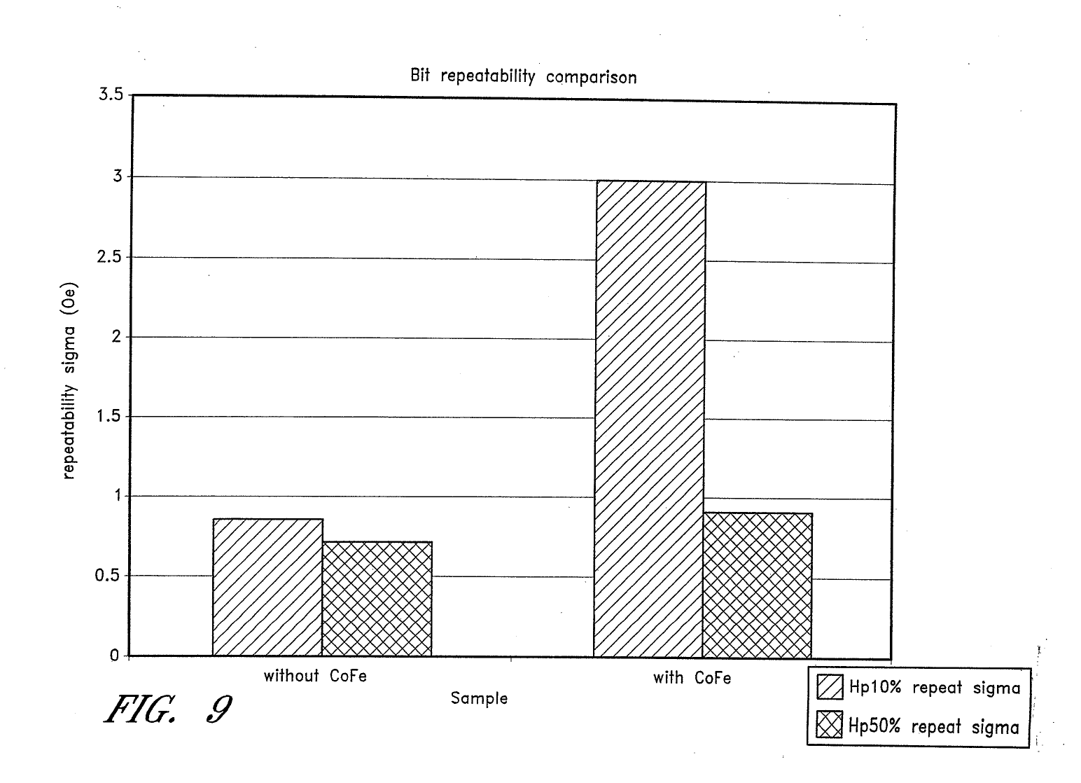

FIG. 9 illustrates mean repeatability in a PSV bit with and without the presence of cobalt-iron added to the PSV cell's nickel-iron composition. Selected bits were tested multiple times to estimate repeatability in the switching field. The test data illustrated in FIG. 9 indicates that repeatability can advantageously be improved for a PSV cell with only nickel-iron so that MRAM memories fabricated using the disclosed PSV cells can advantageously offer improved performance, improved production yields, and lower costs.

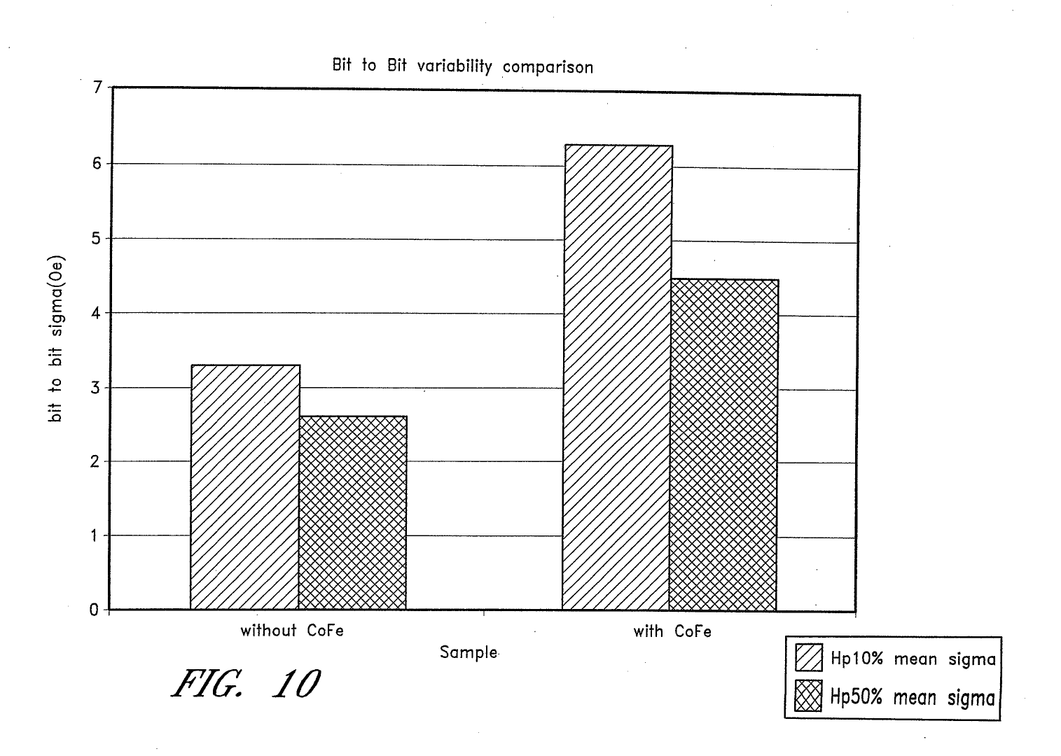

FIG. 10 illustrates bit-to-bit or cell-to-cell variability for multiple cells with and without the presence of cobalt-iron added to the PSV cell's nickel-iron composition. The variability shown in FIG. 10 was calculated assuming a normal distribution for the collected data. The test data illustrated in FIG. 10 indicates that variability can be improved for a PSV cell with only nickel-iron, so that MRAM memories fabricated using the disclosed PSV cells can advantageously offer improved performance, improved production yields, and lower costs.

In both FIGS. 9 and 10, the “Hp 10% mean sigma” data, the data represents variability measured in the strength of the H-field corresponding to where a change of resistance (ΔR/Rₘᵢₙ) of 10% of the maximum change in resistance was observed. For the “Hp 50% mean sigma” data, the data represents variability measured in the strength of the H-field corresponding to where a change of resistance (ΔR/Rₘᵢₙ) of 50% of the maximum change in resistance was observed.

Various embodiments of the invention have been described above. Although this invention has been described with reference to these specific embodiments, the descriptions are intended to be illustrative of the invention and are not intended to be limiting. Various modifications and applications may occur to those skilled in the art without departing from the true spirit and scope of the invention as defined in the appended claims.

We claim:

1. A method of storing and retrieving data comprising:
storing data in a pseudo-spin valve (PSV) by aligning a magnetic orientation of a hard layer of the pseudo-spin valve in either a first direction or a second direction, the second direction different from the first direction, wherein the hard layer consists of a nickel-iron material of a first thickness; and
aligning a magnetic orientation of a soft layer of the PSV to a first direction and to a second direction, wherein the soft layer consists of a nickel-iron material of a second thickness thinner than the first thickness; and
sensing a difference in resistance in the PSV with the magnetic orientation of the soft layer set to the first direction and with the magnetic orientation of the soft layer set to the second direction;

2. The method as defined in claim 1, wherein the soft layer is between about 20% to about 80% of the thickness of the hard layer.

3. The method as defined in claim 1, wherein the nickel-iron material comprises about 50-90% nickel.

4. The method as defined in claim 1, wherein the nickel-iron material comprises about 70-85% nickel.

5. The method as defined in claim 1, wherein the nickel-iron material comprises about 80% nickel.
